(19) United States
(12) Patent Application Publication
(10) Pub. No.: US 2019/0218661 A1
(43) Pub. Date: Jul. 18, 2019

(54) SPOOLED ARRANGEMENT AND PROCESS OF PRODUCING A SPOOLED ARRANGEMENT

(71) Applicant: SILCOTEK CORP., Bellefonte, PA (US)

(72) Inventors: Geoffrey K. WHITE, Cranberry Township, PA (US); Lucas D. PATTERSON, Altoona, PA (US); Corey M. ROBINSON, Bellefonte, PA (US); William David GROVE, Boalsburg, PA (US); Nicholas Peter DESKEVICH, Hollidaysburg, PA (US)

(21) Appl. No.: 16/249,314

(22) Filed: Jan. 16, 2019

Related U.S. Application Data
(60) Provisional application No. 62/617,793, filed on Jan. 16, 2018.

(51) Int. Cl. C23C 16/22

(52) U.S. Cl. CPC C23C 16/22

(57) ABSTRACT

A spooled arrangement and a process of producing a spooled arrangement are disclosed. The spooled arrangement includes a substrate, the substrate being metal or metallic. The substrate has an inner surface and an outer surface, the inner surface and the outer surface being in a furled configuration to define the spooled arrangement. The inner surface and the outer surface have a coating, the coating being an amorphous silicon coating, a silicon-oxygen-carbon-containing coating, a silicon-nitrogen-containing coating, a silicon-fluorine-carbon-containing coating, or a combination thereof. The process includes producing the spooled arrangement.

### FIELD OF THE INVENTION

The present invention is directed to coatings for metal and metallic material. More particularly, the present invention is directed to coatings on spooled arrangements of metal and metallic materials.

### BACKGROUND OF THE INVENTION

Certain thermal chemical vapor deposition coatings have properties that would benefit large metal or metallic structures. However, thermal chemical vapor deposition suffers from a drawback that the articles that can be coated are limited in size to the size of a chamber. Existing chambers are known to have a maximum dimension of about 3 meters. However, materials that can benefit from such coatings can be longer than 3 meters.

Some configurations of metal or metallic structures do not allow of precursors to coatings to be applied in a uniform manner. For example, touch points on coiled, wrapped, or wound configurations, such as spooled arrangements, can cause certain thermal chemical vapor deposition coatings to be unavailable, even though certain applications would benefit from their properties.

Spooled arrangements and processes of producing spooled arrangements that show one or more improvements in comparison to the prior art would be desirable in the art.

### BRIEF DESCRIPTION OF THE INVENTION

In an embodiment, a spooled arrangement includes a substrate having a thickness of at least 0.45 mm, the substrate being metal or metallic. The substrate has an inner surface and an outer surface, the inner surface and the outer surface being in a furled configuration to define the spooled arrangement. The inner surface and the outer surface have a coating, the coating being an amorphous silicon coating, a silicon-oxygen-carbon-containing coating, a silicon-nitrogen-containing coating, a silicon-fluorine-carbon-containing coating, or a combination thereof

In another embodiment, a process includes producing a spooled arrangement. The spooled arrangement includes a substrate having a thickness of at least 0.45 mm, the substrate being metal or metallic. The substrate has an inner surface and an outer surface, the inner surface and the outer surface being in a furled configuration to define the spooled arrangement. The inner surface and the outer surface have a coating, the coating being an amorphous silicon coating, a silicon-oxygen-carbon-containing coating, a silicon-nitrogen-containing coating, a silicon-fluorine-carbon-containing coating.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic perspective view of an embodiment of a process of producing a spooled arrangement, according to an embodiment of the disclosure.

Wherever possible, the same reference numbers will be used throughout the drawings to represent the same parts.

### DETAILED DESCRIPTION OF THE INVENTION

Provided are a spooled arrangement and a process of producing a spooled arrangement. Embodiments of the present disclosure, for example, in comparison to concepts failing to include one or more of the features disclosed herein, permit more economical coating of large materials, permit coating of coils, permit wider applications for coatings previously only available on smaller components, increase inertness, increase resistance to sulfur adsorption, homogenize aesthetics, modify microstructure, modify optical properties, modify porosity, modify corrosion resistance, modify gloss, modify surface features, permit more efficient production of treatments, permit treatment of a wide range of geometries (for example, narrow channels/tubes, three-dimensionally complex geometries, and/or hidden or non-line-of-site geometries, such as, in needles, tubes, probes, fixtures, complex planar and/or non-planar geometry articles, simple non-planar and/or planar geometry articles, and combinations thereof), reduce or eliminate defects/microporosity, permit treatment without use of energy from plasma or microwaves, permit treatment without cooling of an article being treated, permit treatment of a bulk of articles, are capable of being used in or replacing components that are used in industries traditionally believed to be too sensitive for processes that are not flow-through processes (for example, based upon compositional purity, presence of contaminants, thickness uniformity, and/or amount of gas phase nucleation embedded within), allow materials to be used as a substrate that would otherwise produce an electrical arc in a plasma environment, or permit a combination thereof.

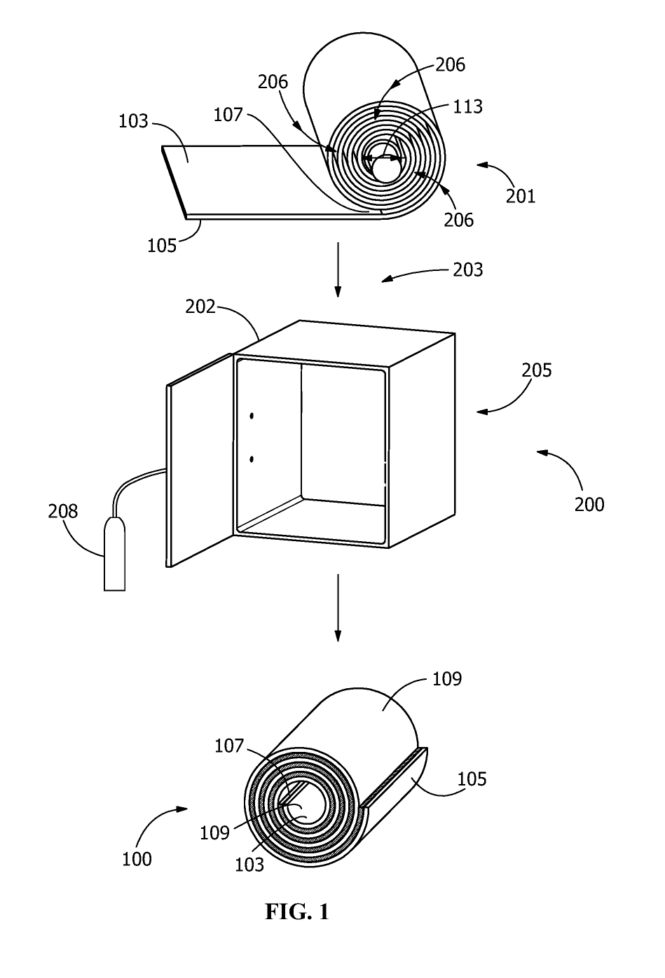

Referring to FIG. 1, in one embodiment, a spooled arrangement 100 includes a substrate 101, the substrate 101 being metal or metallic. The substrate 101 has an inner surface 103 and an outer surface 105. The inner surface 103 and the outer surface 105 are in a furled configuration to define the spooled arrangement 100. As used herein, the term “spooled” and grammatical variations thereof is intended to described a configuration that encompasses a ring-like region and that has overlapping regions.

The substrate 101 is any material capable of being processed in a thermal chemical vapor deposition process. For example, suitable substrates are resistant to thermal conditions of greater than 200° C., greater than 300° C., greater than 350° C., greater than 370° C., greater than 380° C., greater than 390° C., greater than 400° C., greater than 410° C., greater than 420° C., greater than 430° C., greater than 440° C., greater than 450° C., greater than 500° C., between 300° C. and 450° C., between 350° C. and 450° C., between 380° C. and 450° C., between 300° C. and 500° C., between 400° C. and 500° C., or any suitable combination, sub-combination, range, or sub-range therein.

In one embodiment, the substrate 101 is stainless steel, for example, a 300-series stainless steel (such as, 316 stainless steel, 316L stainless steel, or 304 stainless steel) or 400-series stainless steel. In another embodiment, the substrate 101 is an aluminum alloy, for example, a 1000-series aluminum alloy, a 3000-series aluminum alloy, a 4000-series aluminum alloy, or a 6000-series aluminum alloy. Other suitable types of the substrate 101 include, but are not limited to, Hastelloy®, Inconel®, platinum and platinum alloys, titanium and titanium alloys, and combinations thereof.

The substrate 101 is capable of having any at least partially flexible structure capable of being furled. For example, suitable structures for the substrate 101 include, but are not limited to, metal sheeting, porous, non-porous, woven cloth, perforated foil, a lattice structure, and combinations thereof. As used herein, the term “furled” and grammatical variations thereof, refers to being rolled or wrapped in a coil-like orientation. Examples of furled objects consistent with the definition herein include, but are not limited to, metal coils, bolts of fabric, sails wound around masts, wound wire, and window blinds. The term furled is not intended to be limited to tight winding.

According to embodiments of the disclosure, semi-rigid materials that are furled must have a level of flexibility that allows them to be furled without breaking. Although not intending to be bound by theory, such characteristics are defined by thickness, hardness, and grain direction of the substrate 101, which correspond with the material selected as the substrate 101. In one embodiment, a minimum bend radius of the substrate 101 corresponds to the thickness of the substrate by being at least 2.5 times the material thickness or by being at least 3.75 times the material thickness. As will be appreciated by those skilled in the art, various standards for defining such minimum bend radii may be relied upon (such as, those provided by ANSI/ASME).

Suitable thicknesses for the material include, but are not limited to, between 0.45 mm and 3 mm, between 0.45 mm and 0.9 mm, between 1.2 mm and 2 mm, between 2.5 mm and 3 mm, between 0.45 mm and 0.7 mm, between 0.45 mm and 2 mm, between 0.55 mm and 1.6 mm, at least 0.45 mm, at least 1.2 mm, at least 2.5 mm, or any suitable combination, sub-combination, range, or sub-range therein.

In some embodiments, the spool arrangement 100 includes an open region 111 in the center that is substantially large than the minimum bend radius allows. For example, some embodiments of the spool arrangement 100 include the inner surface 103 extending in a substantially circular/cylindrical fashion to form a circle having a diameter 113. Suitable dimensions for the diameter 113 include, but are not limited to, at least 5 cm, at least 10 cm, at least 15 cm, at least 20 cm, at least 30 cm, at least 50 cm, between 5 cm and 10 cm, between 10 cm and 50 cm, between 20 cm and 50 cm, between 20 cm and 30 cm, or any suitable combination, sub-combination, range, or sub-range therein.

In general, the dimensions of the substrate 101 define the dimensions of the spool arrangement 100. Suitable thicknesses 115 of the substrate 101 include, but are not limited to, at least 0.4 cm, at least 1 cm, at least 5 cm, at least 10 cm, between 0.4 and 16 cm, between 1 cm and 10 cm, between 5 cm and 10 cm, between 1 cm and 5 cm, between 0.4 cm and 5 cm, between 0.4 cm and 1 cm, between 0.4 cm and 5 cm, less than 16 cm, or any suitable combination, sub-combination, range, or sub-range therein.

Suitable widths 117 of the substrate 101 include, but are not limited to, at least 1 cm, at least 5 cm, at least 10 cm, at least 30 cm, at least 50 cm, at least 100 cm, at least 200 cm, between 1 cm and 5 cm, between 5 cm and 100 cm, between 30 cm and 200 cm, between 100 cm and 300 cm, less than 300 cm, or any suitable combination, sub-combination, range, or sub-range therein.

Suitable lengths (not shown) of the substrate 101 include, but are not limited to, at least 3 m, at least 10 m, at least 20 m, at least 100 m, at least 300 m, at least 500 me, at least 800 m, at least 1,000 m, at least 1,200 m, at least 1,400 m, between 3 m and 1,500 m, between 10 m and 100 m, between 100 m and 1,500 m, between 300 m and 1,500 m, between 800 m and 1,500 m, between 1,200 m and 1,500 m, less than 1,500 m, or any suitable combination, sub-combination, range, or sub-range therein.

The spooled arrangement 100 is produced according to a process 200. In one embodiment, the process 200 includes producing (step 201) the spooled arrangement 100 with an insert 107 or void region (not shown) separating the inner surface 103 and the outer surface 105 of the substrate 101, positioning (step 203) the spooled arrangement 100 within a thermal chemical vapor deposition chamber 202, and applying (step 205) a coating 109 as a thermal chemical vapor deposition coating to all exposed portions of the substrate 101 of the spooled arrangement 100 within the thermal chemical vapor deposition chamber 202.

In one embodiment, the insert 107 is used during the producing (step 201). The insert 107 defines a flow-path 206 for precursor fluid 208 to reach all exposed portions of the substrate 101, for example, during the applying (step 205) of the coating 109. The insert 107 is capable of withstanding temperatures of the thermal chemical vapor deposition process, for example, as described above. Embodiments of the disclosure include the insert 107 being a flexible porous structure, a lattice structure, a material and/or structure that does not scratch the substrate when the spooled arrangement 100 is moved, or a combination thereof. Additionally or alternatively, in one embodiment, the void region defines the flow-path 206 for the precursor fluid 208. In one embodiment, the coating 109 shows a pattern based upon differing thicknesses corresponding with the insert 107.

In a further embodiment, the insert 107 is positioned on the substrate 101 while the substrate is being rolled into the spool arrangement 100. For example, as shown in FIG. 1, a substantially planar portion 208 of the substrate 101 feeds into a rolling mechanism 210 with the insert 107 being positioned on the substantially planar portion 208. As the substrate 101 moves into the rolling mechanism 210, the insert 107 moves along with the substrate 101, thereby creating the flow-path 206 for the precursor fluid 208 the applying (step 205) of the coating 109.

The precursor fluid 208 is a liquid or gas (but not a plasma) and imparts chemical constituents onto the inner surface 103 and the outer surface 105 when the applying (step 205) of the coating 109 occurs within the chemical vapor deposition chamber 202. The chemical vapor deposition chamber 202 is an enclosed vessel. In one embodiment, the applying (step 205) includes as a first aliquot, then soaking at a temperature above the thermal decomposition temperature of the precursor fluid to produce the coating 109. In a further embodiment, the process includes repeating the introducing of the precursor fluid, for example, as a second aliquot, or introducing a different precursor fluid, to produce additional layers. The soaking is at a temperature above the thermal decomposition temperature of the precursor fluid or the different precursor fluid.

The precursor fluid 208 is cycled in a single cycle or multiple cycles, for example, with intermediate purges (for example, with inert gases, such as, nitrogen, helium, and/or argon). Suitable numbers of cycles include two cycles, three cycles, four cycles, five cycles, six cycles, seven cycles, eight cycles, nine cycles, ten cycles, eleven cycles, twelve cycles, thirteen cycles, fourteen cycles, fifteen cycles, sixteen cycles, or any suitable combination, sub-combination, range, or sub-range therein.

The precursor fluid 208 is capable of being one or more of the following fluids: silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species (for example, dialkylsilyl dihydride and/or alkylsilyl trihydride), thermally-reacted material (for example, carbosilane and/or carboxysilane, such as, amorphous carbosilane and/or amorphous carboxysilane), species capable of a recombination of carbosilyl (disilyl or trisilyl fragments), methyltrimethoxysilane, methyltriethoxysilane, dimethyldimethoxysilane, dimethyldiethoxysilane, trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluoro silyl, fluorinated alkoxysilane, fluoroalkylsilane, fluorosilane, tridecafluoro 1,1,2,2-tetrahydrooctylsilane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,8,9,9,10,10,10-heptadecafluorodecyl) trimethoxy-, or a combination thereof.

Suitable concentrations of thermally-reactive gases used as the precursor fluid 208, by volume, are between 10% and 20%, between 10% and 15%, between 12% and 14%, between 10% and 100%, between 30% and 70%, between 50% and 80%, between 70% and 100%, between 80% and 90%, between 84% and 86%, or any suitable combination, sub-combination, range, or sub-range therein.

In one embodiment, the coating 109 is produced with the partial pressures for the fluid being between 1 Torr and 10 Torr, 1 Torr and 5 Torr, 1 Torr and 3 Torr, 2 Torr and 3 Torr, 10 Torr and 150 Torr, between 10 Torr and 30 Torr, between 20 Torr and 40 Torr, between 30 Torr and 50 Torr, between 60 Torr and 80 Torr, between 50 Torr and 100 Torr, between 50 Torr and 150 Torr, between 100 Torr and 150 Torr, less than 150 Torr, less than 100 Torr, less than 50 Torr, less than 30 Torr, or any suitable combination, sub-combination, range, or sub-range therein.

In one embodiment, the coating 109 is produced with the temperature and the pressure being maintained for at least 10 minutes, at least 20 minutes, at least 30 minutes, at least 45 minutes, at least 1 hour, at least 2 hours, at least 3 hours, at least 4 hours, at least 5 hours, at least 7 hours, between 10 minutes and 1 hour, between 20 minutes and 45 minutes, between 4 and 10 hours, between 6 and 8 hours, or any suitable combination, sub-combination, range, or sub-range therein.

Suitable thicknesses of the coating 109 include, but are not limited to, between 100 nanometers and 10,000 nanometers, between 100 nanometers and 1,000 nanometers, between 100 nanometers and 800 nanometers, between 200 nanometers and 600 nanometers, between 200 nanometers and 10,000 nanometers, between 500 nanometers and 3,000 nanometers, between 500 nanometers and 2,000 nanometers, between 500 nanometers and 1,000 nanometers, between 1,000 nanometers and 2,000 nanometers, between 1,000 nanometers and 1,500 nanometers, between 1,500 nanometers and 2,000 nanometers, 800 nanometers, 1,200 nanometers, 1,600 nanometers, 1,900 nanometers, or any suitable combination, sub-combination, range, or sub-range therein.

Suitable compositions of the coating 109 include the coating 109 being an amorphous silicon coating, a silicon-oxygen-carbon-containing coating, a silicon-nitrogen-containing coating, a silicon-fluorine-carbon-containing coating, or a combination thereof. Further embodiments include the coating 109 having a carbon functionalization.

In one embodiment, the coating 109 is the amorphous silicon coating with the amorphous silicon being at a composition, by weight, of at least 50%.

In one embodiment the coating 109 is the silicon-oxygen-carbon-containing coating with silicon, oxygen, and carbon each being at a composition, by weight, of at least 10%.

In one embodiment the coating 109 is the silicon-nitrogen-containing coating with silicon and nitrogen each being at a composition, by weight, of at least 10%.

In one embodiment the coating 109 is the fluorine-silicon-carbon-containing coating with fluorine, silicon, and carbon each being at a composition, by weight, of at least 10%.

The spooled arrangement 100 is capable of being processed into any suitable article or portion of an article. Suitable articles include, but are not limited to, a blank as is used in pressed sinks and tanks, an exhaust manifold, a shell-and-tube heat exchanger, a plate-fin heat exchanger, a micro-channel heat exchanger, tubing, piping, an automotive application, an aerospace application, a heating-ventilation-air-conditioning-refrigeration application, a ship hull, a building wrap, roofing, flooring, stairs, an architectural element, duct work, an automotive frame, mining equipment, agriculture equipment, a barrel, a chute, a conveyor, a scraper, a blade, a tool, a utility pole, shelving, a panel, a household appliance, an instrument panel, and combinations thereof./

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A spooled arrangement, comprising:
a substrate having a thickness of at least 0.45 mm, the substrate being metal or metallic;
wherein the substrate has an inner surface and an outer surface, the inner surface and the outer surface being in a furled configuration to define the spooled arrangement;
wherein the inner surface and the outer surface have a coating, the coating being an amorphous silicon coating, a silicon-oxygen-carbon-containing coating, a silicon-nitrogen-containing coating, a silicon-fluorine-carbon-containing coating, or a combination thereof.

2. The spooled arrangement of claim 1, wherein the inner surface and the outer surface of the substrate are separated by an insert, the insert defining a flow-path for gas to reach all exposed portions of the substrate.

3. The spooled arrangement of claim 2, wherein the insert is capable of withstanding temperatures of at least 450° C.

4. The spooled arrangement of claim 2, wherein the insert is a flexible porous structure.

5. The spooled arrangement of claim 2, wherein the insert is a lattice structure.

6. The spooled arrangement of claim 2, wherein the insert is does not scratch the substrate when the spooled arrangement is moved.

7. The spooled arrangement of claim 1, wherein the inner surface and the outer surface of the substrate are separated by a void region, the void region defining a flow-path for gas to reach all exposed portions of the substrate.

8. The spooled arrangement of claim 1, wherein the inner surface has a first dimension of greater than 1 meter and a second substantially perpendicular dimension of greater than 100 meters.

9. The spooled arrangement of claim 1, wherein the inner surface has a first dimension of greater than 5 centimeters and a second substantially perpendicular dimension of greater than 100 centimeters.

10. The spooled arrangement of claim 1, wherein the coating is the amorphous silicon coating and further includes a carbon functionalization.

11. The spooled arrangement of claim 1, wherein the coating is the amorphous silicon coating with the amorphous silicon being at a composition, by weight, of at least 50%.

12. The spooled arrangement of claim 1, wherein the coating is the silicon-oxygen-carbon-containing coating with silicon, oxygen, and carbon each being at a composition, by weight, of at least 10%.

13. The spooled arrangement of claim 1, wherein the coating is the silicon-nitrogen-containing coating with silicon and nitrogen each being at a composition, by weight, of at least 10%.

14. The spooled arrangement of claim 1, wherein the coating is the fluorine-silicon-carbon-containing coating with fluorine, silicon, and carbon each being at a composition, by weight, of at least 10%.

15. The spooled arrangement of claim 1, wherein the substrate is stainless steel.

16. The spooled arrangement of claim 1, wherein the substrate is an aluminum alloy.

17. The spooled arrangement of claim 1, wherein the substrate is porous, a woven cloth, perforated foil, a lattice structure, or a combination thereof.

18. A process of producing a spooled arrangement, the spooled arrangement comprising:
a substrate having a thickness of at least 0.45 mm, the substrate being metal or metallic;
wherein the substrate has an inner surface and an outer surface, the inner surface and the outer surface being in a furled configuration to define the spooled arrangement;
wherein the inner surface and the outer surface have a coating, the coating being an amorphous silicon coating, a silicon-oxygen-carbon-containing coating, a silicon-nitrogen-containing coating, a silicon-fluorine-carbon-containing coating.

19. The process of claim 18, comprising:
producing the spooled arrangement with an insert or void region separating the inner surface and the outer surface of the substrate;
positioning the spooled arrangement within a thermal chemical vapor deposition chamber;
applying the coating as a thermal chemical vapor deposition coating to all exposed portions of the substrate of the spooled arrangement within the thermal chemical vapor deposition chamber.

20. The process of claim 19, wherein at least a portion of the spooled arrangement is formed into an article or a portion of an article selected from the group consisting of a blank as is used in pressed sinks and tanks, an exhaust manifold, a shell-and-tube heat exchanger, a plate-fin heat exchanger, a micro-channel heat exchanger, tubing, piping, an automotive application, an aerospace application, a heating-ventilation-air-conditioning-refrigeration application, a ship hull, a building wrap, roofing, flooring, stairs, an architectural element, duct work, an automotive frame, mining equipment, agriculture equipment, a barrel, a chute, a conveyor, a scraper, a blade, a tool, a utility pole, shelving, a panel, a household appliance, an instrument panel, and combinations thereof.
